(19) United States
(12) Patent Application Publication
(10) Pub. No.: US 2026/0286032 A1
(43) Pub. Date: Sep. 24, 2026

(54) PHOTOSENSITIVE RESIN COMPOSITION, CURED PRODUCT, AND SEMICONDUCTOR ELEMENT

(71) Applicant: Resonac Corporation, Minato-ku, Tokyo (JP)

(72) Inventors: Kitaru SATO, Tokyo (JP); Keisuke NISHIDO, Tokyo (JP)

(21) Appl. No.: 19/479,719

(22) PCT Filed: Dec. 2, 2024
(86) PCT No.: PCT/JP2024/042551

§ 371 Date: Oct. 28, 2025

(30) Foreign Application Priority Data
Dec. 5, 2023 (JP) 2023-205348

(51) Int. Cl. C08F 265/10; C08K 5/5397; H10W 70/695

(52) U.S. Cl. CPC C08F 265/10; C08K 5/5397; H10W 70/695; C08F 2810/20

(57) ABSTRACT

A photosensitive resin composition contains a maleimide resin, a (meth)acrylic monomer, a photopolymerization initiator, and an organic solvent, in which the maleimide resin is a reaction product of tetracarboxylic dianhydride (a1), amine (a2), and maleic anhydride (a3), the amine (a2) includes a dimer diamine, the (meth)acrylic monomer includes a bifunctional (meth)acrylic monomer, and the organic solvent includes a high-boiling-point solvent having a boiling point of 150 to 200° C.

### TECHNICAL FIELD

The present disclosure relates to a photosensitive resin composition, a cured product, and a semiconductor element.

### BACKGROUND ART

In accordance with high integration, miniaturization, and micronization of semiconductor elements, insulating films used for surface protective layers, interlayer insulating layers, redistribution layers, and the like of the semiconductor elements are required to have more excellent electrical characteristics, heat resistance, mechanical characteristics, and the like. As a material for forming an insulating film having such characteristics, a photosensitive resin composition containing an alkali-soluble resin has been developed (see, for example, Patent Literatures 1, 2, and 3). These photosensitive resin compositions are applied onto a substrate and dried to form a resin film, and the resin film is exposed and developed to obtain a patterned resin film (a film on which a pattern is formed). Then, a patterned cured film (cured film on which a pattern is formed) can be formed by thermally curing the patterned resin film, and the patterned cured film can be used as an insulating film.

### CITATION LIST

### Patent Literature

Patent Literature 1: Japanese Unexamined Patent Publication No. 2008-309885
Patent Literature 2: Japanese Unexamined Patent Publication No. 2007-057595
Patent Literature 3: International Publication WO 2010/073948

### SUMMARY OF INVENTION

### Technical Problem

In a module requiring high-speed transmission, an insulating film used for a redistribution layer or the like is required to have low dielectric properties (a low dielectric constant and a low dielectric loss tangent) in order to support high frequencies. Furthermore, from the viewpoint of impedance, the film thickness is required to be large. However, the present inventors have found that, when a conventional photosensitive resin composition is used, there are problems in that a thick insulating layer cannot be formed in the first place, or even when a thick insulating film can be formed, via opening properties are poor and low dielectric properties are insufficient. In addition, the present inventors have found that, when a thick coating film is formed using a conventional photosensitive resin composition, there is a problem in that smoothness of a surface of the coating film is poor. When the smoothness of the surface of the coating film is poor, there are problems in that thickness unevenness occurs in lamination, defects occur in wiring formation, and cracks are caused in reliability tests.

An object of the present disclosure is to provide a photosensitive resin composition that has low dielectric properties, can improve smoothness of a surface of a coating film when a thick coating film is formed, and can improve via opening properties when a thick insulating film is formed, a cured product of the photosensitive resin composition, and a semiconductor element.

### Solution to Problem

An aspect of the present disclosure relates to a photosensitive resin composition, a cured product of the photosensitive resin composition, and a semiconductor element.

[1] A photosensitive resin composition containing a maleimide resin, a (meth)acrylic monomer, a photopolymerization initiator, and an organic solvent, in which the maleimide resin is a reaction product of tetracarboxylic dianhydride (a1), amine (a2), and maleic anhydride (a3), the amine (a2) includes a dimer diamine, the (meth)acrylic monomer includes a bifunctional (meth)acrylic monomer, and the organic solvent includes a high-boiling-point solvent having a boiling point of 150 to 200° C.

[2] The photosensitive resin composition according to [1], in which a non-volatile component is 45 to 70 mass %.

[3] The photosensitive resin composition according to [1] or [2], in which a viscosity at 25° C. is 400 to 4000 mPa·s.

[4] A cured product of the photosensitive resin composition according to any one of [1] to [3].

[5] A semiconductor element including a redistribution layer including an insulating film formed of a cured product of the photosensitive resin composition according to any one of [1] to [3].

[6] The semiconductor element according to [5], in which a thickness of the insulating film is 15 μm or more.

### Advantageous Effects of Invention

According to the present disclosure, it is possible to provide a photosensitive resin composition that has low dielectric properties, can improve smoothness of a surface of a coating film when a thick coating film is formed, and can improve via opening properties when a thick insulating film is formed, a cured product of the photosensitive resin composition, and a semiconductor element.

### DESCRIPTION OF EMBODIMENTS

Hereinafter, preferred embodiments of the present disclosure will be described in detail. However, the present disclosure is not limited to the following embodiments, and various modifications can be made within the scope of the gist of the present disclosure.

In the present specification, a numerical range indicated using “to” indicates a range including numerical values described before and after “to” as a minimum value and a maximum value, respectively. In the numerical range described in stages in the present specification, an upper limit value or a lower limit value of a numerical range of a certain stage can be arbitrarily combined with an upper limit value or a lower limit value of a numerical range of another stage. In the numerical range described in the present specification, the upper limit value or the lower limit value of the numerical range may be replaced with a value shown in Examples. “A or B” may include either A or B, or may include both A and B. The materials exemplified in the present specification can be used alone or in combination with two or more kinds thereof unless otherwise specified. When a plurality of materials corresponding to the respective components are present in the composition, a content of each component in the composition means the total amount of the plurality of materials present in the composition unless otherwise specified.

In the present specification, the “layer” and the “film” include not only a structure having a shape formed on the entire surface but also a structure having a shape formed on a part thereof when observed as a plan view. The term “step” includes not only an independent step but also a step that cannot be clearly distinguished from other steps as long as the intended purpose of the step is achieved.

In the present specification, “(meth)acryloyl” means at least one of “acryloyl” and “methacryloyl” corresponding thereto, and the same applies to other similar expressions such as (meth)acrylic acid and (meth)acrylate.

### [Photosensitive Resin Composition]

The photosensitive resin composition according to the present embodiment contains a maleimide resin (hereinafter, also referred to as “component (A)”), a (meth)acrylic monomer (hereinafter, also referred to as “component (B)”), a photopolymerization initiator (hereinafter, also referred to as “component (C)”), and an organic solvent (hereinafter, also referred to as “component (D)”). The maleimide resin is a reaction product of tetracarboxylic dianhydride (a1), amine (a2), and maleic anhydride (a3), and the amine (a2) includes a dimer diamine. The (meth)acrylic monomer includes a bifunctional (meth)acrylic monomer. The organic solvent includes a high-boiling-point solvent having a boiling point of 150 to 200° C.

The photosensitive resin composition according to the present embodiment may further contain, as necessary, a coupling agent (hereinafter, also referred to as “component (E)”), a polymerization inhibitor (hereinafter, also referred to as “component (F)”), a thermal polymerization initiator, a crosslinking agent, a rust inhibitor, and the like. The photosensitive resin composition according to the present embodiment is a negative-type photosensitive resin composition, and a cured product of the photosensitive resin composition can be suitably used as an insulating film having a via, and can be particularly suitably used as a thick insulating film (for example, 15 μm or more). The insulating film is suitably used as a redistribution layer in a semiconductor package such as a fan-out wafer level package (FOWLP) for in-vehicle applications. Hereinafter, each component used in the photosensitive resin composition of the present embodiment will be described in more detail.

### (Component (A): Maleimide Resin)

The maleimide resin according to the present embodiment can be obtained by reacting tetracarboxylic dianhydride (a1) (hereinafter, also referred to as “component (a1)”), amine (a2) (hereinafter, also referred to as “component (a2)”), and maleic anhydride (a3) (hereinafter, also referred to as “component (a3)”). That is, the component (A) is a maleimide resin obtained by reacting the component (a1), the component (a2), and the component (a3). Here, the component (a2) includes a dimer diamine. The component (A) may have a plurality of maleimide groups in the molecule. The component (A) may be a bismaleimide resin. The components (A) can be used alone or in combination with two or more kinds thereof.

As the tetracarboxylic dianhydride of the component (a1), those known as a raw material of polyimide can be used. Examples of the component (a1) include pyromellitic dianhydride, 4,4′-(hexafluoroisopropylidene)diphthalic anhydride, 1,3,3a,4,5,9b-hexahydro-5-(tetrahydro-2,5-dioxo-3-furanyl) naphtho[1,2-c]furan-1,3-dione, 4,4′-oxydiphthalic anhydride, 3,3′,4,4′-diphenylsulfonetetracarboxylic dianhydride, 3,3′,4,4′-biphenyltetracarboxylic dianhydride, 3,3′,4,4′-benzophenonetetracarboxylic dianhydride, 4,4′-(4,4′-isopropylidenediphenoxy)diphthalic anhydride, 1,2,3,4-butanetetracarboxylic dianhydride, 1,2,3,4-cyclobutane tetracarboxylic dianhydride, 1,2,3,4-cyclopentane tetracarboxylic dianhydride, 1,2,3,4-tetramethyl-1,2,3,4-cyclobutane tetracarboxylic dianhydride, bicyclo[2.2.2]oct-7-ene-2,3,5,6-tetracarboxylic dianhydride, bis(1,3-dioxo-1,3-dihydroisobenzofuran-5-carboxylic acid) 1,4-phenylene, 9,9-bis(3,4-dicarboxyphenyl)fluorene dianhydride, 4,4′-(ethyne-1,2-diyl)diphthalic anhydride, 5-(2,5-dioxotetrahydrofuryl)-3-methyl-3-cyclohexene-1,2-dicarboxylic anhydride, dicyclohexyl-3,4,3′,4′-tetracarboxylic dianhydride, 3,4′-oxydiphthalic anhydride, 3,4′-biphthalic anhydride, norbornane-2-spiro-α-cyclopentanone-α′-spiro-2″-norbornane-5,5″,6,6″-tetracarboxylic dianhydride, 5,5′-bis-2-norbornene-5,5′,6,6′-tetracarboxylic acid-5,5′,6,6′-dianhydride, and 9,9-bis[4-(3,4-dicarboxyphenoxy)phenyl]fluorene dianhydride. Among them, from the viewpoints of heat resistance and availability, pyromellitic dianhydride and 3,3′,4,4′-biphenyltetracarboxylic dianhydride are preferable. The components (a1) can be used alone or in combination with two or more kinds thereof.

The component (a2) contains a dimer diamine. The dimer diamine is, for example, a compound derived from a dimer acid which is a dimer of an unsaturated fatty acid such as oleic acid as described in Japanese Unexamined Patent Publication No. H9-12712. By using a dimer diamine as the component (a2), the dielectric properties of the cured product can be lowered. In the present embodiment, a known dimer diamine can be used without particular limitation. The dimer diamine preferably includes, for example, at least one of a compound represented by the following General Formula (1) and a compound represented by the following General Formula (2).

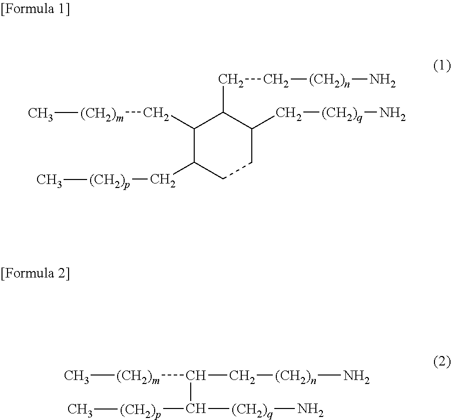

In Formulas (1) and (2), m, n, p, and q each represent an integer of 1 or more selected so as to satisfy m+n=6 to 17 and p+q=8 to 19, and a bond indicated by a broken line represents a carbon-carbon single bond or a carbon-carbon double bond. Provided that when the bond indicated by the broken line is a carbon-carbon double bond, Formulas (1) and (2) have a structure in which the number of hydrogen atoms bonded to each carbon atom constituting the carbon-carbon double bond is subtracted by one from the numbers indicated in Formulas (1) and (2).

The dimer diamine may be represented by General Formula (2) from the viewpoints of solubility in an organic solvent, heat resistance, heat resistant adhesiveness, low viscosity, and the like, and may particularly be a compound represented by the following Formula (3).

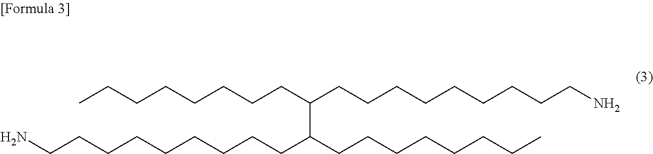

Examples of a commercially available product of the dimer diamine include PRIAMINE 1075 and PRIAMINE 1074 (both manufactured by Croda Japan K.K.).

The component (a2) may further contain another amine other than the dimer diamine (hereinafter, also referred to as “second amine”). The second amine is an amine that does not correspond to the dimer diamine described above. The second amine may be a diamine or a triamine, or may be a diamine. By using an alicyclic diamine as the second amine, a dielectric constant can be further reduced. By using an aromatic diamine as the second amine, the elastic modulus, Tg, and CTE of the cured product are improved.

When the second amine is a diamine, examples of the diamine include 1,3-diaminopropane, norbornanediamine, 4,4′-methylenedianiline, 1,3-bis[2-(4-aminophenyl)-2 propyl]benzene, 4,4′-diamino-2,2′-bis(trifluoromethyl)biphenyl, 2,2-bis[4-(4-aminophenoxy)phenyl]hexafluoropropane, 9,9-bis(4-aminophenyl)fluorene, 9,9-bis[3-fluoro-4-aminophenyl]fluorene, 9,9-bis[4-(4-aminophenoxy)phenyl]fluorene, 1,3-bis(aminomethyl)cyclohexane, 1,4-bis(aminomethyl)cyclohexane, bis(aminomethyl)norbornane, 4,4′-(hexafluoroisopropylidene)dianiline, 3(4), 8(9)-bis(aminomethyl)tricycl [5.2.1.0^{2,6}]decane, 1,3-cyclohexanediamine, 1,4-cyclohexanediamine, isophoronediamine, 4,4′-methylenebis(cyclohexylamine), 4,4′-methylenebis(2-methylcyclohexylamine), 1,1-bis(4-aminophenyl)cyclohexane, 2,7-diaminofluorene, 4,4′-ethylenedianiline, 4,4′-methylenebis(2,6-diethylaniline), 4,4′-methylenebis(2-ethyl-6-methylaniline), 2,2-bis[4-(4-aminophenoxy)phenyl]propane, bis [4-(4-aminophenoxy)phenyl]methane, 4,4′-bis(4-aminophenoxy)biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, (4,4′-diamino)diphenyl ether, (3,3′-diamino)diphenyl ether, paraphenylenediamine, orthophenylenediamine, meta-phenylenediamine, 2,2′-dimethylbiphenyl-4,4′-diamine, bis[4-(3-aminophenoxy)phenyl]sulfone, and bis[4-(4-aminophenoxy)phenyl]sulfone. These second amines can be used alone or in combination with two or more kinds thereof.

When the second amine is a triamine, examples of the triamine include tris(aminomethyl)amine, tris(2-aminoethyl)amine, tris(2-aminopropyl)amine, 2-(aminomethyl)-2-methyl-1,3-propanediamine, a trimer triamine, 3,4,4′-triaminodiphenyl ether, 1,2,4-triaminobenzene, 1,3,5-triaminobenzene, 1,2,3-triaminobenzene, 1,3,5-triazine-2,4,6-triamine, 2,4,6-triaminopyrimidine, 1,3,5-tris(4-aminophenyl)benzene, and 1,3,5-tris(4-aminophenoxy)benzene. Among them, from the viewpoint of photocurability, aliphatic amines and alicyclic amines are preferable, and norbornanediamine, isophoronediamine, and tris(2-aminoethyl)amine are more preferable. These second amines can be used alone or in combination with two or more kinds thereof.

The second amine may include one or both of the diamine and triamine described above. In addition, the second amine may include an amine other than the diamine and the triamine.

In the component (a2), a molar ratio of the second amine to the total amount of amines (the number of moles of the second amine/(the number of moles of the dimer diamine+the number of moles of the second amine)) may be 0.70 or less, and may be 0.50 or less. When the ratio is 0.70 or less, the dielectric properties of the cured product can be further reduced.

When the second amine includes a diamine, a molar ratio of the diamine in the second amine to the total amount of diamines in the component (a2) (the number of moles of diamine in the second amine/(the number of moles of the dimer diamine+the number of moles of diamine in the second amine)) may be 0.70 or less, and may be 0.50 or less. When the ratio is 0.70 or less, the dielectric properties of the cured product can be further reduced.

The component (A) can be produced by various known methods. For example, first, the component (a1) and the component (a2) are subjected to a polyaddition reaction at a temperature of about 60 to 120° C. and preferably 70 to 90° C., for usually about 0.1 to 2 hours and preferably 0.1 to 1.0 hour. Next, the obtained polyaddition product is further subjected to an imidization reaction, that is, a dehydration cyclization reaction, at a temperature of about 80 to 250° C. and preferably 100 to 200° C. for about 0.5 to 30 hours and preferably 0.5 to 10 hours. Subsequently, the product obtained by the dehydration cyclization reaction and the component (a3) are subjected to a maleimidation reaction, that is, a dehydration cyclization reaction, at a temperature of about 60 to 250° C. and preferably 80 to 200° C. for about 0.5 to 30 hours and preferably 0.5 to 10 hours, thereby obtaining a target component (A).

In the imidization reaction or the maleimidation reaction, various known reaction catalysts, dehydrating agents, and organic solvents can be used.

Examples of the reaction catalyst include aliphatic tertiary amines such as triethylamine, aromatic tertiary amines such as dimethylaniline, heterocyclic tertiary amines such as pyridine, picoline, and isoquinoline, and organic acids such as methanesulfonic acid and p-toluenesulfonic acid monohydrate. Examples of the dehydrating agent include aliphatic acid anhydrides such as acetic anhydride and aromatic acid anhydrides such as benzoic anhydride.

Examples of the organic solvent used in the reaction include aromatic hydrocarbons such as benzene, toluene, xylene, and mesitylene; alcohol-based solvents such as methanol, ethanol, isopropyl alcohol, butanol, pentanol, hexanol, propanediol, and phenol; ketone-based solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, butyl formate, and γ-butyrolactone; glycol ether-based solvents such as ethylene glycol mono-n-butyl ether, ethylene glycol mono-iso-butyl ether, ethylene glycol mono-tert-butyl ether, diethylene glycol mono-n-butyl ether, diethylene glycol mono-iso-butyl ether, triethylene glycol monoethyl ether, triethylene glycol mono-n-butyl ether, and tetraethylene glycol mono-n-butyl ether; and nitrogen-containing compounds such as N,N-dimethylformamide, N,N-dimethylacetamide, N-methyl-2-pyrrolidone, N-ethyl-2-pyrrolidone, 3-methoxy-N,N-dimethylpropanamide, and 3-butoxy-N,N-dimethylpropanamide. The organic solvents can be used alone or in combination with two or more kinds thereof.

As the organic solvent used in the reaction, an organic solvent having a boiling point of 150 to 200° C. is preferably used. Examples of the organic solvent having a boiling point of 150 to 200° C. include 1,2,3,5-tetramethylbenzene (boiling point: 198° C.), n-propylbenzene (boiling point: 160° C.), 2-ethyltoluene (boiling point: 164° C.), 3-ethyltoluene (boiling point: 158° C.), 4-ethyl-m-xylene (boiling point: 186° C.), 1,2,3-trimethylbenzene (hemimellitene, boiling point: 176° C.), phenetole (ethoxybenzene, boiling point: 173° C.), cumene (boiling point: 152° C.), 1,2,4-trimethylbenzene (pseudocumene, boiling point: 169° C.), 1,3,5-trimethylbenzene (mesitylene, boiling point: 165° C.), anisole (boiling point: 154° C.), butyl cellosolve (boiling point: 171° C.), methyl carbitol (boiling point: 194° C.), dipropylene glycol monomethyl ether (boiling point: 188° C.), dipropylene glycol dimethyl ether (boiling point: 171° C.), N,N-dimethylformamide (boiling point: 153° C.), and N,N-dimethylacetamide (boiling point: 165° C.). In addition, as the organic solvent having a boiling point of 150 to 200° C., a petroleum-based solvent such as solvent naphtha (boiling point: 150 to 185° C.), which is a distillation fraction of naphtha, may also be used. The solvent naphtha may include trimethylbenzene. Specific examples of the solvent naphtha include T-SOL 100 (trade name, manufactured by ENEOS Corporation), Swasol 1000 (trade name, manufactured by Cosmo Matsuyama Oil Co., Ltd.), and Ipsol 100 (trade name, manufactured by Idemitsu Kosan Co., Ltd.).

The component (A) can be purified by various known methods, and the purity can be increased. For example, first, the component (A) dissolved in an organic solvent and pure water are placed in a separatory funnel. Next, the separatory funnel is shaken and allowed to stand. Subsequently, after an aqueous layer and an organic layer are separated, only the organic layer is recovered, such that the component (A) can be purified.

A presumed structure of the component (A) produced by the above method is shown in the following General Formula (4).

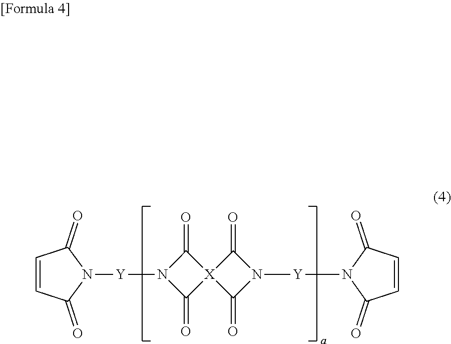

In General Formula (4), X each independently represents a tetravalent organic group, Y each independently represents a divalent organic group, and a represents an integer of 1 or more. Provided that at least one of the plurality of Y's represents a divalent organic group derived from the dimer diamine described above. In addition, X and Y may be organic groups having an aliphatic group, an alicyclic structure, or an aromatic ring, and may contain a heteroatom.

A molecular weight of the component (A) can be controlled by the number of moles of the component (a1) and the component (a2), and the molecular weight can be reduced as the number of moles of the component (a1) decreases relative to the number of moles of the component (a2). For the purpose of facilitating achievement of the effects of the present disclosure, the number of moles of the component (a1) relative to 1 mole of the component (a2), that is, [the number of moles of the component (a1)]/[the number of moles of the component (a2)], is usually about 0.30 to 0.95, and preferably in a range of 0.50 to 0.85.

As the molecular weight of the component (A), from the viewpoints of solubility in a solvent and heat resistance, a weight average molecular weight (Mw) is preferably 3000 to 40000, more preferably 4000 to 30000, and still more preferably 5000 to 28000 or 7000 to 27000. When the weight average molecular weight is 40000 or less, the solubility in an organic solvent is improved, and when the weight average molecular weight is 3000 or more, the effect of improving heat resistance tends to be sufficiently obtained. The Mw can be measured by gel permeation chromatography (GPC), and can be converted using a calibration curve of standard polystyrene.

From the viewpoint of further enhancing the balance between low dielectric properties and fine processability, a content of the component (A) is preferably more than 50 parts by mass, and may be 55 to 99 parts by mass, 60 to 96 parts by mass, 70 to 92 parts by mass, or 80 to 90 parts by mass, when the total amount of the component (A) and the component (B) is 100 parts by mass.

### (Component (B): (Meth)acrylic Monomer)

The (meth)acrylic monomer is a compound having a (meth)acryloyl group. The component (B) is a compound having one or more (meth)acryloyl groups, and may be a polyfunctional compound having two or more (meth)acryloyl groups. The component (B) includes at least a bifunctional (meth)acrylic monomer having two (meth)acryloyl groups. When the component (B) includes a bifunctional (meth)acrylic monomer, photocurability is improved, curing can be performed with a low exposure dose, and fine vias can be opened. When the component (B) is a polyfunctional compound, for example, the component (B) can be crosslinked not only with another component (B) but also with the component (A) at the time of exposure of the photosensitive layer. The components (B) can be used alone or in combination with two or more kinds thereof.

Examples of the bifunctional (meth)acrylic monomer include tricyclodecanedimethanol di(meth)acrylate, ethoxylated bisphenol A di(meth)acrylate, propoxylated ethoxylated bisphenol A di(meth)acrylate, dioxane glycol di(meth)acrylate, 1,6-hexanediol di(meth)acrylate, 1,9-nonanediol di(meth)acrylate, 1,10-decanediol di(meth)acrylate, neopentyl glycol di(meth)acrylate, dipentaerythritol di(meth)acrylate, ethoxylated isocyanuric acid di(meth)acrylate, tripropylene glycol di(meth)acrylate, polypropylene glycol di(meth)acrylate, and polyethylene glycol di(meth)acrylate. Among them, tricyclodecanedimethanol di(meth)acrylate is preferable from the viewpoints of low dielectric properties and heat resistance.

The component (B) may further include another (meth)acrylic monomer other than the bifunctional (meth)acrylic monomer. Examples of the other (meth)acrylic monomer include isobornyl (meth)acrylate, dicyclopentanyl (meth)acrylate, tris(2-(meth)acryloyloxyethyl) isocyanurate, pentaerythritol tetra(meth)acrylate, ethoxylated isocyanuric acid tri(meth)acrylate, trimethylolpropane tri(meth)acrylate, and ethoxylated trimethylolpropane tri(meth)acrylate. Among them, isobornyl (meth)acrylate, dicyclopentanyl (meth)acrylate, and tris(2-(meth)acryloyloxyethyl) isocyanurate are preferable from the viewpoints of low dielectric properties and heat resistance.

From the viewpoint of further enhancing the balance between low dielectric properties and fine processability, a content of the component (B) is preferably less than 50 parts by mass, and may be 1 to 40 parts by mass, 2 to 30 parts by mass, 3 to 20 parts by mass, or 5 to 15 parts by mass, when the total amount of the component (A) and the component (B) is 100 parts by mass.

From the viewpoints of low dielectric properties and photocurability, a content of the bifunctional (meth)acrylic monomer is preferably less than 50 parts by mass, and may be 1 to 40 parts by mass, 2 to 30 parts by mass, 3 to 20 parts by mass, or 5 to 15 parts by mass, when the total amount of the component (A) and the component (B) is 100 parts by mass.

### (Component (C): Photopolymerization Initiator)

The photopolymerization initiator (hereinafter, also referred to as “component (C)”) is not particularly limited as long as it is a compound that initiates polymerization by radiation with active light (ultraviolet light or the like), and examples thereof include an alkylphenone-based photopolymerization initiator, an acylphosphine oxide-based photopolymerization initiator, an intramolecular hydrogen abstraction-type photopolymerization initiator, and an oxime ester-based photopolymerization initiator.

The alkylphenone-based photopolymerization initiator can be purchased, for example, as Omnirad 651, Omnirad 184, Omnirad 1173, Omnirad 2959, Omnirad 127, Omnirad 907, Omnirad 369, or Omnirad 379EG manufactured by IGM Resins B.V. The acylphosphine oxide-based photopolymerization initiator can be purchased, for example, as Omnirad 819 or Omnirad TPO H manufactured by IGM Resins B.V. The intramolecular hydrogen abstraction-type photopolymerization initiator can be purchased, for example, as Omnirad MBF or Omnirad 754 manufactured by IGM Resins B.V. The oxime ester-based photopolymerization initiator can be purchased, for example, as Irgacure OXE01 or Irgacure OXE02 manufactured by BASF Japan Ltd. In order to promote the photoreaction, a titanocene-based photopolymerization initiator (for example, Irgacure 784, manufactured by BASF Japan Ltd.) may be used in combination.

A content of the component (C) may be 0.1 to 10 parts by mass, 0.5 to 8 parts by mass, or 1 to 5 parts by mass, with respect to 100 parts by mass of the total amount of the component (A) and the component (B) from the viewpoints of photocurability and storage stability.

### (Component (D): Organic Solvent)

The photosensitive resin composition according to the present embodiment contains an organic solvent for dissolving and dispersing each component. This makes it possible to facilitate coating of the photosensitive resin composition on a substrate and to form a coating film having a uniform thickness. The component (D) contains a high-boiling-point solvent having a boiling point of 150 to 200° C. in order to improve the smoothness of the surface of the coating film when a thick coating film is formed, and to improve the via opening properties when a thick insulating film is formed. The components (D) may be used alone or in combination with two or more kinds thereof.

Examples of the high-boiling-point solvent having a boiling point of 150 to 200° C. include, for example, as the organic solvent having a boiling point of 150 to 200° C., 1,2,3,5-tetramethylbenzene (boiling point: 198° C.), n-propylbenzene (boiling point: 160° C.), 2-ethyltoluene (boiling point: 164° C.), 3-ethyltoluene (boiling point: 158° C.), 4-ethyl-m-xylene (boiling point: 186° C.), 1,2,3-trimethylbenzene (hemimellitene, boiling point: 176° C.), phenetole (ethoxybenzene, boiling point: 173° C.), cumene (boiling point: 152° C.), 1,2,4-trimethylbenzene (pseudocumene, boiling point: 169° C.), 1,3,5-trimethylbenzene (mesitylene, boiling point: 165° C.), anisole (boiling point: 154° C.), butyl cellosolve (boiling point: 171° C.), methyl carbitol (boiling point: 194° C.), dipropylene glycol monomethyl ether (boiling point: 188° C.), dipropylene glycol dimethyl ether (boiling point: 171° C.), N,N-dimethylformamide (boiling point: 153° C.), and N,N-dimethylacetamide (boiling point: 165° C.). In addition, as the organic solvent having a boiling point of 150 to 200° C., a petroleum-based solvent such as solvent naphtha (boiling point: 150 to 185° C.), which is a distillation fraction of naphtha, may also be used. Specific examples of the solvent naphtha are as described above. Among them, solvent naphtha, pseudocumene, and mesitylene are preferable from the viewpoint of availability. The high-boiling-point solvents can be used alone or in combination with two or more kinds thereof. The boiling point of the high-boiling-point solvent having a boiling point of 150 to 200° C. may be 150 to 190° C., or may be 150 to 185° C., from the viewpoints of further improving the smoothness of the surface of the coating film when a thick coating film is formed and further improving the via opening properties when a thick insulating film is formed.

The component (D) may further include another solvent other than the high-boiling-point solvent having a boiling point of 150 to 200° C. Examples of the other solvent include ketones such as methyl ethyl ketone and cyclopentanone; aromatic hydrocarbons such as toluene and xylene; glycol ethers such as methyl cellosolve and propylene glycol monomethyl ether; esters such as ethyl acetate and butyl acetate; and nitrogen-containing compounds.

A content of the component (D) is preferably in such an amount that the non-volatile component in the photosensitive resin composition is 45 to 70 mass %, 50 to 65 mass %, or 50 to 60 mass % from the viewpoints of further improving the smoothness of the surface of the coating film when a thick coating film is formed and further improving the via opening properties when a thick insulating film is formed. Here, the non-volatile component refers to the non-volatile component excluding volatile substances (such as water and a solvent) contained in the photosensitive resin composition, and also includes a component in a liquid, syrupy, or waxy state at room temperature (around 25° C.). The non-volatile component of the photosensitive resin composition can be measured by the method described in Examples.

A content of the high-boiling-point solvent having a boiling point of 150 to 200° C. may be 50 to 100 mass %, 60 to 100 mass %, or 70 to 100 mass %, based on the total amount of component (D) from the viewpoints of further improving the smoothness of the surface of the coating film when a thick coating film is formed and further improving the via opening properties when a thick insulating film is formed.

### (Component (E): Coupling Agent)

The photosensitive resin composition according to the present embodiment may further contain a coupling agent from the viewpoint of improving the adhesion of the cured product of the photosensitive resin composition. The component (E) may be a silane coupling agent. The silane coupling agent may have, for example, a group such as a vinyl group, an epoxy group, a styryl group, an acryloyl group, a methacryloyl group, an amino group, a ureido group, an isocyanate group, an isocyanurate group, or a mercapto group.

Examples of the silane coupling agent having a vinyl group include KBM-1003 and KBE-1003 (trade names, manufactured by Shin-Etsu Chemical Co., Ltd., the same applies hereinafter). Examples of the silane coupling agent having an epoxy group include KBM-303, 402, and 403, KBE-402 and 403, X-12-981S, and X-12-984S. Examples of the silane coupling agent having a styryl group include KBM-1403.

Examples of the silane coupling agent having a methacryloyl group include KBM-502 and 503 and KBE-502 and 503. Examples of the silane coupling agent having an acryloyl group include KBM-5103, X-12-1048, and X-12-1050. Examples of the silane coupling agent having an amino group include KBM-602, 603, 903, 573, and 575, KBE-903 and 9103P, and X-12-972F. Examples of the silane coupling agent having a ureido group include KBE-585. Examples of the silane coupling agent having an isocyanate group include KBE-9007 and X-12-1159L. Examples of the silane coupling agent having an isocyanurate group include KBM-9659. Examples of the silane coupling agent having a mercapto group include KBM-802 and 803, X-12-1154, and X-12-1156. The silane coupling agent may be a silane coupling agent having a methacryloyl group. The silane coupling agents can be used alone or in combination with two or more kinds thereof.

A content of the component (E) may be 0.01 to 10 parts by mass, 0.1 to 8 parts by mass, or 0.5 to 5 parts by mass, with respect to 100 parts by mass of the total amount of the component (A) and the component (B).

### (Component (F): Polymerization Inhibitor)

The photosensitive resin composition according to the present embodiment may further contain a polymerization inhibitor from the viewpoint of storage stability.

Examples of the component (F) include 4-tert-butylcatechol, 4-hydroxy-2,2,6,6-tetramethylpiperidine-1-oxy radical, p-methoxyphenol, diphenyl-p-benzoquinone, benzoquinone, hydroquinone, pyrogallol, phenothiazine, resorcinol, ortho-dinitrobenzene, para-dinitrobenzene, meta-dinitrobenzene, phenanthraquinone, N-phenyl-2-naphthylamine, cupferron, 2,5-toluquinone, tannic acid, para-benzylaminophenol, tris(4-tert-butyl-3-hydroxy-2,6-dimethylbenzyl) isocyanuric acid, and nitrosamines. The polymerization inhibitors may be used alone or in combination with two or more kinds thereof.

A content of the component (F) may be 0.01 to 10 parts by mass, 0.05 to 5 parts by mass, or 0.10 to 2 parts by mass, with respect to 100 parts by mass of the total amount of the component (A) and the component (B).

### (Rust Inhibitor)

The photosensitive resin composition according to the present embodiment may further contain a rust inhibitor from the viewpoint of suppressing corrosion of copper wiring or preventing discoloration. Examples of the rust inhibitor include a triazole derivative such as benzotriazole and a tetrazole derivative. The rust inhibitors may be used alone or in combination with two or more kinds thereof.

A content of the rust inhibitor may be 0.01 to 10 parts by mass, 0.03 to 5 parts by mass, or 0.05 to 3 parts by mass, with respect to 100 parts by mass of the total amount of the component (A) and the component (B).

### (Crosslinking Agent)

The photosensitive resin composition according to the present embodiment may further include a crosslinking agent other than the component (B). The crosslinking agent may be a polymerizable crosslinking agent. The polymerizable group may be a photopolymerizable group or a thermopolymerizable group. Examples of the polymerizable group include an allyl group and a vinyl group from the viewpoints of dielectric properties and heat resistance. The crosslinking agent may be a polyfunctional compound having two or more polymerizable groups. In addition, the crosslinking agent can be crosslinked, for example, not only with another crosslinking agent but also with the component (A) or the component (B) at the time of exposure of the photosensitive layer. In addition, the crosslinking agent can be crosslinked, for example, with another polymerizable crosslinking agent at the time of heating the resin film after pattern formation. The crosslinking agents can be used alone or in combination with two or more kinds thereof.

Examples of the polymerizable crosslinking agent having an allyl group include 1,3,4,6-tetraallyl glycoluril, triallyl isocyanurate, diallyl monoglycidyl isocyanurate, diallyl monomethyl isocyanurate, diallyl isocyanurate, triallyl trimellitate, and triallyl ortho-formate.

Examples of the polymerizable crosslinking agent having a vinyl group include a polyvinyl benzyl compound and a polyvinyl benzyl ether compound.

The polymerizable crosslinking agent having an allyl group or a vinyl group may include at least one selected from the group consisting of 1,3,4,6-tetraallyl glycoluril, triallyl isocyanurate, diallyl isocyanurate, and a polyvinyl benzyl ether compound from the viewpoint of dielectric properties and fine processability, and may include 1,3,4,6-tetraallyl glycoluril from the viewpoint of dielectric properties.

A content of the crosslinking agent may be 0.1 to 20 parts by mass, 0.5 to 15 parts by mass, or 1 to 10 parts by mass, with respect to 100 parts by mass of the total amount of the component (A) and the component (B) from the viewpoints of photocurability and dielectric properties.

### (Thermal Polymerization Initiator)

The photosensitive resin composition according to the present embodiment may further contain a thermal polymerization initiator from the viewpoint of promoting a polymerization reaction of a thermally polymerizable crosslinking agent. As the thermal polymerization initiator, a compound that decomposes by heating during curing to generate radicals and promotes a polymerization reaction between the thermally polymerizable crosslinking agent and the component (A) or the component (B) is preferable. Examples of the thermal polymerization initiator include an organic peroxide.

Examples of the organic peroxide include methyl ethyl ketone peroxide, methylcyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl 4,4-bis(t-butylperoxy) valerate, 2,2-bis(t-butylperoxy) butane, 1,1-bis(t-butylperoxy)-2-methylcyclohexane, t-butyl hydroperoxide, p-menthane hydroperoxide, 1,1,3,3-tetramethylbutyl hydroperoxide, t-hexylhydroperoxide, dicumyl peroxide, 2,5-dimethyl-2,5-bis(t-butylperoxy) hexane, α,α′-bis(t-butylperoxy)diisopropylbenzene, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumylperoxyneodecanoate, 1,1,3,3-tetramethylbutylperoxyneodecanoate, 1-cyclohexyl-1-methylethyl peroxyneodecanoate, t-hexylperoxyneodecanoate, t-butylperoxyneodecanoate, t-hexylperoxypivalate, t-butylperoxypivalate, 2,5-dimethyl-2,5-bis(2-ethylhexanoylperoxy) hexane, 1,1,3,3-tetramethylbutylperoxy-2-ethylhexanoate, 1-cyclohexyl-1-methylethylperoxy-2-ethylhexanoate, t-hexylperoxy-2-ethylhexanoate, t-butylperoxy-2-ethylhexanoate, t-butylperoxyisobutyrate, t-butylperoxymaleic acid, t-butylperoxylaurate, t-butylperoxy-3,5,5-trimethylhexanoate, t-butylperoxyisopropyl monocarbonate, butylperoxy-2-ethylhexyl monocarbonate, 2,5-dimethyl-2,5-bis(benzoylperoxy) hexane, t-butylperoxyacetate, t-hexylperoxybenzoate, t-butylperoxy-m-toluoyl benzoate, t-butylperoxybenzoate, bis(t-butylperoxy) isophthalate, t-butylperoxyallyl monocarbonate, and 3,3′,4,4′-tetra(t-butylperoxycarbonyl)benzophenone.

A content of the thermal polymerization initiator is not particularly limited, and may be 0.1 to 10.0 parts by mass, 0.5 to 5.0 parts by mass, or 0.7 to 3.0 parts by mass, with respect to 100 parts by mass of the total amount of the component (A), the component (B), and the crosslinking agent.

The preparation means, conditions, and the like of the photosensitive resin composition are not particularly limited. Examples thereof include a method in which various components are sufficiently uniformly stirred and mixed in predetermined blending amounts by a mixer or the like, and then kneaded by using a mixing roll, an extruder, a kneader, a roll, an extruder, or the like. The kneading method is not particularly limited.

A viscosity of the photosensitive resin composition according to the present embodiment at 25° C. may be 400 to 4000 mPas, 400 to 3000 mPa's, or 500 to 2000 mPa's from the viewpoint of coatability. The viscosity of the photosensitive resin composition at 25° C. can be measured by the method described in Examples.

A relative dielectric constant of the cured product of the photosensitive resin composition according to the present embodiment at 10 GHz may be 2.80 or less, 2.75 or less, or 2.70 or less. A dielectric loss tangent of the cured product of the photosensitive resin composition at 10 GHz may be 0.0060 or less, 0.0050 or less, 0.0045 or less, or 0.0040 or less. The relative dielectric constant and the dielectric loss tangent can be measured by the method described in Examples using a cured film of the photosensitive resin composition.

An elastic modulus of the cured product of the photosensitive resin composition according to the present embodiment at 20° C. may be 50 to 1500 MPa, 100 to 1000 MPa, or 150 to 700 MPa from the viewpoint of low warpage. The elastic modulus at 20° C. can be measured by the method described in Examples using a cured film of the photosensitive resin composition.

A glass transition temperature (Tg) of the cured product of the photosensitive resin composition according to the present embodiment may be 0 to 200° C., 10 to 150° C., or 20 to 100° C. from the viewpoint of heat resistance. The Tg can be measured by the method described in Examples using a cured film of the photosensitive resin composition.

A coefficient of thermal expansion (CTE) of the cured product of the photosensitive resin composition according to the present embodiment may be 50 to 200 ppm/° C., 60 to 180 ppm/° C., or 70 to 160 ppm/° C. from the viewpoint of low warpage and reliability. The CTE can be measured by the method described in Examples using a cured film of the photosensitive resin composition.

A 5% weight loss temperature of the cured product of the photosensitive resin composition according to the present embodiment may be 300 to 500° C., 320 to 450° C., or 340 to 420° C. from the viewpoint of heat resistance. The 5% weight loss temperature can be measured by the method described in Examples using a cured film of the photosensitive resin composition.

An elongation at break of the cured product of the photosensitive resin composition according to the present embodiment may be 50 to 250%, 70 to 200%, or 80 to 160% from the viewpoint of reliability. The elongation at break can be measured by the method described in Examples using a cured film of the photosensitive resin composition.

The photosensitive resin composition according to the present embodiment can form a thick insulating film having a via hole, can improve the smoothness of the surface of the coating film when a thick coating film is formed, and can improve the via opening properties when a thick insulating film is formed. In addition, the photosensitive resin composition according to the present embodiment can form an insulating film exhibiting low dielectric properties and excellent insulation reliability. By using the photosensitive resin composition according to the present embodiment, it is possible to produce a semiconductor element provided with an interlayer insulating layer formed from a cured product of the photosensitive resin composition, and an electronic device including the semiconductor element.

The semiconductor element may be, for example, a memory, a package, or the like having a multilayer wiring structure, a redistribution structure, or the like. Examples of the electronic device include a mobile phone, a smartphone, a tablet device, a personal computer, and a hard disk suspension. By providing an insulating film formed using the photosensitive resin composition of the present embodiment, it is possible to provide a semiconductor element and an electronic device having excellent reliability. A semiconductor element and an electronic device provided with a redistribution layer including an insulating film formed of a cured product of the photosensitive resin composition of the present embodiment are suitable as semiconductor elements and electronic devices for in-vehicle applications.

### [Method for Forming Insulating Film]

The formation of the insulating film having a via hole can be performed by a photolithography method. That is, a method for forming an insulating film according to the present embodiment includes a step of applying a photosensitive resin composition onto a substrate and drying the photosensitive resin composition to form a photosensitive layer, and a step of exposing and developing the photosensitive layer to form an insulating film having a via hole. The method for forming an insulating film according to the present embodiment may include a step of further thermally curing the photosensitive layer after exposure and/or after development. Hereinafter, each step will be described in more detail.

First, the photosensitive resin composition of the present embodiment is applied onto a substrate and dried to form a photosensitive layer. In this step, the photosensitive resin composition of the present embodiment is spin-coated, using a spin coater or the like, onto a substrate such as a glass substrate, a semiconductor, a metal oxide insulator (for example, TiO₂ or SiO₂), a silicon nitride substrate, a silicon substrate, or a copper substrate, to form a coating film. By using the photosensitive resin composition of the present embodiment, a thick coating film having excellent smoothness can be formed by spin coating.

The substrate on which the coating film is formed is dried using a hot plate, an oven, or the like. A drying temperature and a drying time are not particularly limited, but may be 80 to 150° C. for 3 to 30 minutes. As a result, a photosensitive layer is formed on the substrate. A thickness of the photosensitive layer may be 15 μm or more, 20 to 50 μm, or 20 to 40 μm.

Next, the photosensitive layer is irradiated with active light in a pattern so that a via hole is formed in the photosensitive layer after development, thereby exposing the photosensitive layer and photocuring the exposed portions. The exposure of the photosensitive layer can be performed using a known projection exposure method, contact exposure method, direct imaging exposure method, or the like.

A light source of the active light is not particularly limited as long as it is a commonly used known light source, and for example, light sources that effectively emit ultraviolet light, such as a carbon arc lamp, a mercury vapor arc lamp, an ultra-high-pressure mercury lamp, a high-pressure mercury lamp, a xenon lamp, a gas laser such as an argon laser, a solid-state laser such as a YAG laser, and a semiconductor laser such as a gallium nitride-based blue-violet laser are used. In addition, a light source that effectively emits visible light, such as a photographic floodlight bulb or a solar lamp, may be used. Among these, from the viewpoint of further improving the via opening properties, a light source capable of emitting i-line monochromatic light having an exposure wavelength of 365 nm, a light source capable of emitting h-line monochromatic light having an exposure wavelength of 405 nm, or a light source capable of emitting active light having an exposure wavelength of ihg mixed line may be used, and among them, a light source capable of emitting i-line monochromatic light having an exposure wavelength of 365 nm may be preferably used. Examples of the light source capable of emitting i-line monochromatic light having an exposure wavelength of 365 nm include an ultra-high pressure mercury lamp.

After exposure, an insulating film having a via hole can be formed by removing the unexposed portions of the photosensitive layer with a developer. As the developer, an aqueous alkali solution such as sodium carbonate, sodium hydroxide, potassium hydroxide, sodium silicate, ammonia, ethylamine, diethylamine, triethylamine, triethanolamine, or tetramethylammonium hydroxide (TMAH), or an organic solvent such as cyclopentanone, cyclohexanone, or propylene glycol monomethyl ether acetate (PGMEA) is suitably used. When development is performed using a developer, the development can be performed by a method such as shower development, spray development, immersion development, or paddle development.

By the above method, it is possible to form an insulating film formed of a cured product of the photosensitive resin composition of the present embodiment. A thickness of the insulating film may be 15 μm or more, 20 to 50 μm, or 20 to 40 μm. By using the photosensitive resin composition of the present embodiment, even when a thick insulating film having the above thickness is formed, excellent via opening properties can be obtained. In addition, by forming a redistribution layer including a thick insulating film having the above thickness using the photosensitive resin composition of the present embodiment, it is possible to improve the high-frequency characteristics of a semiconductor element provided with this redistribution layer.

A diameter (opening diameter) of the via hole of the insulating film may be 5 to 150 μm, 10 to 100 μm, or 20 to 60 μm from the viewpoint of increasing the density of the semiconductor package. By using the photosensitive resin composition of the present embodiment, even when a via hole having the above diameter is formed, excellent via opening properties can be obtained.

An aspect ratio (the thickness of the insulating film/the diameter of the via hole) obtained by dividing the thickness of the insulating film by the diameter of the via hole provided in the insulating film may be 0.30 to 1.50, 0.40 to 1.40, or 0.50 to 1.20. By using the photosensitive resin composition of the present embodiment, even when a via hole having a large aspect ratio is formed, excellent via opening properties can be obtained.

### EXAMPLES

Hereinafter, the present disclosure will be specifically described with reference to Examples and Comparative Examples, but the present disclosure is not limited thereto. Note that, in each example, parts and % are on a mass basis unless otherwise specified.

### <Measurement Methods>

### (Weight Average Molecular Weight)

A weight average molecular weight (Mw) of a bismalcimide resin was measured by gel permeation chromatography (GPC). 50 μL of a sample obtained by dissolving the bismaleimide resin in tetrahydrofuran (THF) so as to have a concentration of 3 mass % was injected into columns (GL-R420×1, GL-R430×1, and GL-R440×1 (all columns are manufactured by Hitachi High-Tech Fielding Corporation)) heated to 30° C., and the measurement was performed under conditions of a flow rate of 1.6 mL/min using THE as a developing solvent. Note that, as a detector, L-3350 RI detector (manufactured by Hitachi, Ltd.) was used, and the weight average molecular weight (Mw) was calculated from the elution time based on a molecular weight/elution time curve created using standard polystyrene (manufactured by Tosoh Corporation).

### (Non-Volatile Component (N.V.))

0.75 g±0.25 g of the solution of the bismaleimide resin or the photosensitive resin composition was weighed into an aluminum dish using an analytical balance, and then dried at 150° C. for 0.5 hours in a hot air dryer, and the non-volatile component (N.V.) was calculated by the following equation. The results are shown in Table 1.

$$N . V . ( mass \% ) = \{ ( W 3 - W 1 ) / W 2 \} \times 100$$

W1: Mass (g) of empty aluminum dish
W2: Mass (g) of solution of bismaleimide resin or photosensitive resin composition before drying
W3: Mass (g) of aluminum dish after drying+remaining bismaleimide resin or photosensitive resin composition

### (Viscosity)

The viscosity of the photosensitive resin composition was measured using an E-type viscometer (trade name “RE85R,” manufactured by Toki Sangyo Co., Ltd.). The measurement was performed under the conditions of a sample amount of 1.0 mL, a measurement temperature of 25.0° C., a preheating time of 2 minutes, and a measurement time of 3 minutes. The results are shown in Table 1.

### <Synthesis of Maleimide Resin>

### Synthesis Example 1

Into a 1 L flask vessel equipped with a condenser, a nitrogen inlet tube, a thermocouple, a stirrer, and a vacuum pump, 54.68 parts by mass of pyromellitic dianhydride (manufactured by Daicel Corporation), 432.92 parts by mass of T-SOL100 (trade name, solvent naphtha, manufactured by ENEOS Corporation), and 94.78 parts by mass of Solmix A-11 (trade name, an alcohol-based solvent containing ethanol as a main agent, manufactured by Japan Alcohol Trading Co., Ltd.) were charged. After the charging, the temperature was raised to 80° C. and maintained for 0.5 hours, and 179.46 parts by mass of dimer diamine (trade name “PRIAMINE 1075”, manufactured by Croda Japan K.K.) was added dropwise. After the dropwise addition, the mixture was maintained at 80° C. for 0.5 hours, and then 6.42 parts by mass of an aqueous methanesulfonic acid solution (70 mass % aqueous solution, trade name “Lutropur MSA”, manufactured by BASF SE) was added. Thereafter, the pressure in the reaction vessel was reduced from atmospheric pressure by 0.03 MPa, and the temperature was raised to 160° C. while removing the alcohol-based solvent from the reaction solution. After raising the temperature, a dehydration cyclization reaction was performed at 160° C. for 2 hours, during which water and the alcohol-based solvent in the reaction solution were removed, and a solution containing an intermediate polyimide resin was obtained. Subsequently, the pressure in the reaction vessel was returned to atmospheric pressure, the obtained solution containing the polyimide resin was cooled to 130° C., and 24.58 parts by mass of maleic anhydride (manufactured by FUSO CHEMICAL CO., LTD.) was added. Thereafter, the pressure in the reaction vessel was reduced from atmospheric pressure by 0.03 MPa, and the temperature was raised to 160° C. After raising the temperature, a dehydration cyclization reaction was performed at 160° C. for 4 hours, during which water in the reaction solution was removed, and a solution containing a bismaleimide resin was obtained.

The obtained solution containing the bismaleimide resin was placed in a separatory funnel, 1200 parts by mass of pure water was added, and the separatory funnel was shaken and allowed to stand. After standing, the organic layer and the aqueous layer were separated, and then only the organic layer was recovered. The recovered organic layer was charged into a 1 L glass vessel equipped with a condenser, a nitrogen inlet tube, a thermocouple, a stirrer, and a vacuum pump, heated to 88 to 93° C., and water was removed. Thereafter, the temperature was raised to 100° C., and the solvent was partially removed for 0.5 hours under a pressure reduced by 0.1 MPa from atmospheric pressure, thereby obtaining a solution of a bismaleimide resin (A-1). The Mw of the bismaleimide resin (A-1) was 17300, and the N.V. was 56.0 mass %. The organic solvent contained in the solution of the bismaleimide resin (A-1) is T-SOL 100 (solvent naphtha).

### Synthesis Example 2

Into a 2 L pressure-resistant SUS vessel (manufactured by Todoroki Sangyo Co., Ltd.) equipped with a cooling tube, a separation tank, a nitrogen inlet tube, a thermocouple, and a stirrer, and capable of performing a reaction under a pressurized state while refluxing a solvent, 111 parts by mass of pyromellitic dianhydride (manufactured by Daicel Corporation), 907 parts by mass of toluene (manufactured by Wako Pure Chemical Industries, Ltd.), and 200 parts by mass of methanol (manufactured by Daishin Chemical Co., Ltd.) were charged. Next, nitrogen gas was introduced into the vessel to pressurize it to a gauge pressure of 250 kPa, and then the temperature was raised to 80° C. and maintained for 0.5 hours. Subsequently, 368 parts by mass of dimer diamine (trade name “PRIAMINE 1075”, manufactured by Croda Japan K.K.) was added dropwise at a dropping rate of 12.3 g/min. After the dropwise addition, the mixture was maintained at 80° C. for 0.5 hours, and then 6.5 parts by mass of methanesulfonic acid was added. Thereafter, the temperature was raised to 160° C. while removing the alcohol-based solvent from the reaction solution. After raising the temperature, a dehydration cyclization reaction was performed at 160° C. for 2 hours, during which water and the alcohol-based solvent in the reaction solution were removed, and a solution containing an intermediate polyimide resin was obtained. Subsequently, the obtained solution containing the polyimide resin was cooled to 130° C., and 50 parts by mass of maleic anhydride (manufactured by FUSO CHEMICAL CO., LTD.) was added. Thereafter, the temperature was raised to 160° C. After raising the temperature, a dehydration cyclization reaction was performed at 160° C. for 4 hours, during which water in the reaction solution was removed, and a solution containing a bismaleimide resin was obtained. Thereafter, purification was performed in the same manner as in Synthesis Example 1 to obtain a solution of a bismaleimide resin (A-2). The Mw of the bismaleimide resin (A-2) was 16700, and the N.V. was 56.0 mass %. The organic solvent contained in the solution of the bismaleimide resin (A-2) is toluene.

### Examples 1 to 4 and Comparative Examples 1 and 2

### <Production of Photosensitive Resin Composition and Cured Sheet>

The respective components shown below were blended in the composition (unit: parts by mass) shown in Table 1 to prepare a photosensitive resin composition. Next, using an applicator, the photosensitive resin composition was applied onto FILMBYNA (registered trademark) (PET film, manufactured by Fujimori Kogyo Co., Ltd., trade name “NS14”, film thickness: 75 μm) so as to have a thickness of 50 μm after drying, and a drying treatment was performed at 130° C. for 10 minutes in a dryer. Subsequently, UV irradiation was performed under a condition of an accumulated light amount of 3000 mJ/cm² using a UV irradiator (UV irradiation apparatus with conveyor, manufactured by GS Yuasa Corporation, metal halide lamp (MAL 500NAL) used). After the UV irradiation, a curing treatment was performed at 180° C. for 10 minutes in a nitrogen dryer to produce a cured sheet.

### Component (A): Maleimide Resin

Bismaleimide Resins (A-1) and (A-2) Produced in Synthesis Examples 1 and 2

### Component (B): (Meth)acrylic Monomer

(B-1) A-DCP (trade name, tricyclodecane dimethanol diacrylate, manufactured by Shin-Nakamura Chemical Co., Ltd.)
(B-2) IBXA (trade name, isobornyl acrylate, manufactured by Osaka Organic Chemical Industry Ltd.)

### Component (C): Photopolymerization Initiator

(C-1) Omnirad 819 (trade name, phenylbis(2,4,6-trimethylbenzoyl)phosphine=oxide, manufactured by IGM Resins B.V.)

### Component (D): Organic Solvent

(D-1) T-SOL100 (trade name, solvent naphtha, ENEOS Corporation, boiling point: 154 to 181° C.)
(D-2) Toluene (manufactured by Yamaichi Chemical Industries Co., Ltd., boiling point: 110° C.)

### Component (E): Coupling Agent

(E-1) KBM-503 (trade name: 3-methacryloxypropyltrimethoxysilane, manufactured by Shin-Etsu Silicone Co., Ltd.)

### Component (F): Polymerization Inhibitor

(F-1) TEMPOL (4-hydroxy-2,2,6,6-tetramethylpiperidin-1-oxyl free radical, manufactured by Tokyo Chemical Industry Co., Ltd.)

### [Evaluation of Photosensitive Properties]

<Appearance after Application and Film Thickness after Application>

The photosensitive resin composition was applied to a silicon wafer (12 inch) using a spin coater so that the film thickness after drying was 25 μm. The appearance of the coating film after application was visually observed and evaluated according to the following criteria. Thereafter, the coating film was dried on a hot plate at 130° C. for 10 minutes and cooled to room temperature to form a photosensitive layer. The film thickness of the photosensitive layer was measured with a film thickness meter. The results are shown in Table 1.

(Criteria for Evaluation of Appearance after Coating)
A: No holes, irregularities, or the like were observed on the surface of the coating film, and the smoothness was good.
B: Holes, irregularities, or the like were observed on the surface of the coating film, and the smoothness was poor.
   <Appearance after Development and Via Opening Properties>

The photosensitive resin composition was applied onto a silicon wafer (12 inch) with Cu sputtering using a spin coater so that the film thickness after drying was 25 μm. After the application, the coating film was dried on a hot plate at 130° C. or 100° C. (Table 1 “Drying temperature after coating [° C.]”) for 10 minutes to form a photosensitive layer. For the obtained photosensitive layer, UV irradiation was performed under a condition of an accumulated light amount of 3000 mJ/cm² using an i-line stepper exposure apparatus (manufactured by CERMA PRECISION, INC., trade name “Stepper-NMS-Scók”) and a negative-type pattern mask having via diameters of 100, 80, 60, 40, 35, 30, and 25 μm. After the UV irradiation, a heat treatment was performed on a hot plate at 80° C. for 3 minutes. After the heat treatment, development was performed twice using a paddle-type developing apparatus (manufactured by Mikasa Co., Ltd., trade name “AD-3000”) at room temperature with cyclopentanone for 25 seconds, rinsing with PGMEA (propylene glycol monomethyl ether acetate) was performed once for 10 seconds, and then air-drying was performed at 3000 rpm, thereby obtaining a patterned cured film (insulating film) after development. The appearance (presence or absence of peeling) of the obtained patterned cured film was visually observed and evaluated according to the following criteria. In addition, the thickness of the patterned cured film was measured with a film thickness meter. Further, as the via opening properties of the patterned cured film, the minimum via diameter at which there is no residue at the via bottom and the via is opened was determined by observation with a metallurgical microscope. The results are shown in Table 1. Note that when the result of via opening properties is “>100”, it means that even at a via diameter of 100 μm, the via was not opened without residue. In addition, for the patterned cured film in which the via was opened without residue, Table 1 shows the aspect ratio obtained by dividing the thickness of the patterned cured film by the minimum via diameter at which the via was opened without residue.

(Criteria for Evaluation of Appearance after Development)
A: No peeling of the patterned cured film
B: Peeling of a part of the patterned cured film
C: Peeling present over the entire surface of the patterned cured film

### [Evaluation of Cured Product Properties]

### <Dielectric Properties>

A test piece having a sample size of 50 mm×100 mm was prepared using the cured sheet. Using this test piece, a relative permittivity (Dk) and a dielectric loss tangent (Df) at 10 GHz were measured at room temperature (20° C.) with a network analyzer (trade name “P5003A”, manufactured by KEYSIGHT Technologies, Inc.) and a split-cylinder resonator (manufactured by KEYSIGHT Technologies, Inc.). The results are shown in Table 2.

### <Elastic Modulus and Tg>

A test piece having a sample size of 20 mm×10 mm was prepared using the cured sheet, and a modulus at 20° C. and Tg (tan & peak) were measured under conditions of a frequency of 1 Hz, a measurement temperature of −40° C. to 220° C., and a heating rate of 10° C./min using a dynamic mechanical analyzer (trade name “DMS6100”, manufactured by SII Nanotechnology Inc.). The results are shown in Table 2. Note that, for those having two tan 8 peaks, two peak temperatures (i) and (ii) were shown as Tg in Table 2.

### <Coefficient of Thermal Expansion (CTE)>

A test piece having a size of 30 mm×4 mm was prepared using the cured sheet. Using this test piece, a coefficient of thermal expansion (CTE) was measured with a thermomechanical analyzer (trade name “TMA/SS7100”, manufactured by Hitachi High-Tech Science Corporation). The measurement mode was a tensile mode, the measurement load was 5 mN, the measurement atmosphere was an air atmosphere, the heating rate was 5° C./min, and the measurement temperature range was-50 to 250° C. The measurement result in the range of −20° C. to 40° C. in the 2nd run was taken as the CTE. The results are shown in Table 2.

### <5% Weight Loss Temperature>

The cured sheet was weighed in an amount of 6.0 to 10.0 mg into an open-type sample container (trade name “P/N SSC000E030”, manufactured by Seiko Instruments Inc.), and a 5% weight loss temperature (Tas) was measured under conditions of a nitrogen flow rate of 300 mL/min and a heating rate of 10° C./min. As a measuring apparatus, TG/DTA7200 (manufactured by Hitachi High-Tech Science Corporation) was used. The results are shown in Table 2.

### <Elongation at Break>

A test piece having a size of 50 mm×10 mm was prepared using the cured sheet. Using this test piece, an autograph (trade name “AGS-X”, manufactured by Shimadzu Corporation) was used, the test piece was fixed at both ends by 10 mm to the axis, and an elongation at break was measured at a measurement temperature of 25° C. and a tensile speed of 10 mm/min. The results are shown in Table 2.

TABLE 1

| | | Example | Example | Example | Example | Comparative | Comparative | Comparative |
|---|---|---|---|---|---|---|---|---|
| | | 1 | 2 | 3 | 4 | Example 1 | Example 2 | Example 3 |
| Component | Solution of (A-1) | 169.64 | 160.71 | 160.71 | 160.71 | 178.57 | — | 160.71 |
| (A) | N.V. = 56.0 | | | | | | | |
| | mass % | | | | | | | |
| | Solution of (A-2) | — | — | — | — | — | 178.57 | — |
| | N.V. = 56.0 | | | | | | | |
| | mass % | | | | | | | |
| Component | (B-1)A-DCP | 5.00 | 10.00 | 5.00 | 10.00 | — | — | — |
| (B) | (B-2)IBXA | — | — | 5.00 | — | — | | 10.00 |
| Component | (C-1)Omnirad | 4.00 | 4.00 | 4.00 | 4.00 | 4.00 | 4.00 | 4.00 |
| (C) | 819 | | | | | | | |
| Component | (D-1)T-SOL100 | 8.00 | 15.00 | 3.00 | 7.00 | 1.50 | — | 0.50 |
| (D) | (D-2) Toluene | — | — | — | — | — | 1.50 | — |
| Component | (E-1)KBM-503 | 0.50 | 0.50 | 0.50 | 0.50 | 0.50 | 0.50 | 0.50 |
| (E) | | | | | | | | |
| Component | (F-1)TEMPOL | — | — | — | 0.25 | — | — | — |
| (F) | | | | | | | | |

| | | | | | | | |
|---|---|---|---|---|---|---|---|
| N.V. [mass %] | 55.8 | 54.9 | 55.8 | 57.4 | 56.6 | 56.6 | 53.8 |
| Viscosity [mPa · s] | 1164 | 912 | 1198 | 1278 | 1270 | 710 | 1125 |
| Drying temperature after | 130 | 130 | 100 | 130 | 130 | 130 | 100 |
| coating [° C.] | | | | | | | |
| Appearance of coating film | A | A | A | A | A | B | A |
| (smoothness) | | | | | | | |
| Thickness of photosensitive | 25 | 25 | 25 | 25 | 25 | 25 | 25 |
| layer [μm] | | | | | | | |
| Appearance of cured film | A | A | A | A | B | B | B |
| (presence or absence of | | | | | | | |
| peeling) | | | | | | | |
| Thickness of cured film [μm] | 25 | 25 | 25 | 25 | 25 | 25 | 25 |
| Via opening properties [μm] | 25 | 25 | 25 | 25 | >100 | >100 | >100 |
| Aspect ratio | 1.0 | 1.0 | 1.0 | 1.0 | — | — | — |

TABLE 2

| | | | | | | Comparative | Comparative | Comparative |
|---|---|---|---|---|---|---|---|---|
| | | Example 1 | Example 2 | Example 3 | Example 4 | Example 1 | Example 2 | Example 3 |
| Dielectric | Dk | 2.45 | 2.50 | 2.44 | 2.42 | 2.44 | 2.40 | 2.39 |
| properties | Df | 0.0026 | 0.0030 | 0.0026 | 0.0031 | 0.0018 | 0.0019 | 0.0022 |
| DMA | Elastic | 335 | 500 | 150 | 550 | 230 | 260 | 280 |
| | modulus | | | | | | | |
| | [MPa] | | | | | | | |
| | Tg [° C.] | (i) 14 | (i) 20 | 46 | (i) 19 | 34 | 36 | 44 |
| | | (ii) 87 | (ii) 89 | | (ii) 87 | | | |
| TMA | CTE | 153 | 146 | 152 | 146 | 155 | 156 | 155 |
| | [ppm/° C.] | | | | | | | |
| TGA | T_{d5} [° C.] | 379 | 375 | 378 | 380 | 410 | 405 | 348 |

| | | | | | | | |
|---|---|---|---|---|---|---|---|
| Elongation at break (%) | 120 | 106 | 126 | 110 | 154 | 153 | 154 |

1. A photosensitive resin composition comprising a maleimide resin, a (meth)acrylic monomer, a photopolymerization initiator, and an organic solvent,
wherein the maleimide resin is a reaction product of tetracarboxylic dianhydride (a1), amine (a2), and maleic anhydride (a3),
the amine (a2) includes a dimer diamine,
the (meth)acrylic monomer includes a bifunctional (meth)acrylic monomer, and the organic solvent includes a high-boiling-point solvent having a boiling point of 150 to 200° C.

2. The photosensitive resin composition according to claim 1, wherein a non-volatile component is 45 to 70 mass %.

3. The photosensitive resin composition according to claim 1, wherein a viscosity at 25° C. is 400 to 4000 mPa s.

4. A cured product of the photosensitive resin composition according to claim 1.

5. A semiconductor element comprising a redistribution layer including an insulating film formed of a cured product of the photosensitive resin composition according to claim 1.

6. The semiconductor element according to claim 5, wherein a thickness of the insulating film is 15 μm or more.
